(19) United States
(12) Patent Application Publication
(10) Pub. No.: US 2025/0328708 A1
(43) Pub. Date: Oct. 23, 2025

(54) OBJECT-CENTRIC CONTACT MODELING AND HAND GRASP GENERATION

(71) Applicant: Adobe Inc., San Jose, CA (US)

(72) Inventors: Yang Zhou, Mountain View, CA (US); Shaowei Liu, Urbana, IL (US); Jimei Yang, Mountain View, CA (US)

(21) Appl. No.: 18/638,487

(22) Filed: Apr. 17, 2024

(51) Int. Cl. G06F 30/23; G06T 17/10

(52) U.S. Cl. CPC G06F 30/23; G06T 17/10

(57) ABSTRACT

In some embodiments, a computing system receives a representation of an object from a client device. The computing system generates a contact representation for hand-object interaction based on the representation of the object. The object-centric contact representation includes a contact map indicating contact points on the representation of the object, a hand part map indicating hand parts contacting the object, and a direction map comprising contact directions of the hand parts contacting the object. The computing system generates a hand grasp representation with respect to the object based on the contact representation using a model-based optimization algorithm. The computing system provides the hand grasp representation to the client device.

### FIELD OF THE INVENTION

This disclosure relates generally to generative artificial intelligence. More specifically, but not by way of limitation, this disclosure relates to object-centric contact modeling and hand grasp generation.

### BACKGROUND OF THE INVENTION

A human hand can interact with an object in different ways, for example different ways to grasp the object using a single hand. Modeling hand-object interaction has gained substantial importance across various domains in animation, games, and augmented and virtual reality. Currently approaches often rely on a contact map applied on object point clouds. However, simply modeling the hand-object interaction based on the contact map does not fully capture the details of the contact. A single contact map falls short of representing the structured uncertainty inherent in hand-object interaction. The lack of thorough and precise modeling can result in unnatural and unrealistic interaction models, for example with insufficient contact or excessive penetration.

### BRIEF SUMMARY OF THE INVENTION

Certain embodiments involve generating a digital hand grasp representation with respect to an object. In one example, a computing system receives an object representation, such as a point cloud of an object from a user computing device. The computing system generates a contact model representing hand-object interaction based on the object representation. The contact model can include a contact map indicating contact locations on the object representation, a hand part map indicating hand parts contacting the object, and a direction map indicating contact directions of hand parts contacting the object. The three components can be determined based on a sequential and conditional framework. For example, the computing system determines the contact map based on the object representation, determines the hand part map based on the object representation and the contact map, and determines the direction map based on the object representation and the hand part map. The computing system generates a digital hand grasp representation based on the contact model and a hand model using an optimization algorithm. The computing system provides the hand grasp representation to the user computing device.

### BRIEF DESCRIPTION OF THE DRAWINGS

Features, embodiments, and advantages of the present disclosure are better understood when the following Detailed Description is read with reference to the accompanying drawings.

FIG. 1 depicts an example of a computing environment in which a hand grasp generation server generates a hand grasp representation for a digital object, according to certain embodiments of the present disclosure.

FIG. 2 depicts an example of a process for generating a representation of a hand grasping an object, according to certain embodiments of the present disclosure.

FIG. 3 depicts an example of a diagram for generating a hand grasp representation, according to certain embodiments of the present disclosure.

FIG. 4A depicts an example of a hand part in a piecewise SDF hand model contacting an object surface, according to certain embodiments of the present disclosure.

FIG. 4B depicts an example of a contact direction of the hand part in FIG. 4A, according to certain embodiments of the present disclosure.

FIG. 5 depicts an example of a diagram for training a sequence of CVAE models, according to certain embodiments of the present disclosure.

FIG. 6 depicts an example of a diagram generating a contact representation using a sequence of trained CVAE models, according to certain embodiments of the present disclosure.

FIG. 7 depicts an example of a comparison between recovered hand grasp representations using different methods and ground truth representations, according to certain embodiments of the present disclosure.

FIG. 8 depicts an example of a comparison of hand grasp representations generated by the proposed method and baseline grasp generation methods, according to certain embodiments of the present disclosure.

FIG. 9 depicts an example of the computing system for implementing certain embodiments of the present disclosure.

### DETAILED DESCRIPTION OF THE INVENTION

Certain embodiments involve object-centric contact modeling and hand grasp generation. For instance, a computing system receives a representation (e.g., a point cloud) of an object from a client device. The computing system can generate a contact representation of hand-object interaction based on the representation of the object. The contact representation can include a contact map representing contact points on the object, a hand part map representing hand parts contacting the object, and a direction map representing with respect to centers of the hand parts contacting the object. The contact map, hand part map, and direction map can be determined sequentially using a sequence of conditional variational autoencoder (CVAE) models. The computing system can generate a representation of a hand grasping the object based on the contact representation of hand-object interaction using a model-based optimization algorithm.

The following non-limiting example is provided to introduce certain embodiments. In this example, a hand grasp generation system communicates with a client device over a network. The client device can send a digital representation of an object to the hand grasp generation system. The digital representation of the object can be a point cloud, while other types of representation may also work, such as a mesh model of the object.

In some examples, the hand grasp generation system extracts multiple object features based on the point cloud of the object. The hand grasp generation system determines the contact map based on the multiple object features using the first CVAE model of the sequence of CVAE models. The first CVAE model includes a contact encoder and a contact decoder. The hand grasp generation system then generates the hand part map based on the multiple object features and the contact map using the second CVAE model of the sequence of CVAE models. The second CVAE model includes a part encoder and part decoder. The hand grasp generation system then generates the direction map based on the multiple object features and the hand part map using the third CVAE model of the sequence of CVAE models. The third CVAE model includes a direction encoder and a direction decoder.

Based on the contact representation, the hand grasp generation system then generates a representation of a hand grasping the object using a model-based optimization algorithm. A piecewise Signed Distance Function (SDF) model is used to model a hand. The hand can be modeled with 16 parts with the piecewise SDF model. The piecewise SDF hand model includes pose parameters corresponding to different hand parts and a shape parameter corresponding to the hand overall. The hand grasp generation system can implement an algorithm (e.g., Adam optimization algorithm) to determine optimized multiple pose parameters corresponding to the multiple hand parts grasping the object and the shape parameter corresponding to the hand grasping the object.

The hand grasp generation system provides the representation of the hand grasping the object to the client device, which can display the representation of the hand grasping the object on a display device associated with the client device. The representation of the hand grasping the object can be rotated or manipulated to show the grasp from different perspectives. The hand grasp representation can be used in animation, games, augmented reality, virtual reality, or any other suitable areas. For example, during creation of an animated video, hand grasp representations are needed to show that animated characters interact with virtual objects by hand realistically. As another example, hand grasp representations are needed to simulate a physical hand manipulating an object in virtual reality.

Certain embodiments of the present disclosure overcome the disadvantages of the prior art, by generating an object-centric contact model including a contact map, a hand part map, and a direction map. Contacting hand part and contacting direction information learned by sequential CVAE models provides more accurate and complete contact representation, which provides sufficient contact and reduces penetration. Hand pose and hand space optimization based on the contact representation and a piecewise hand model makes hand grasp representations more realistic and diverse. Thus, the hand grasp representation generated based on the object-centric contact model are more natural and realistic, with improved contact, reduced penetration, increased stability, more naturalness, and greater diversity, compared to those generated by existing methods.

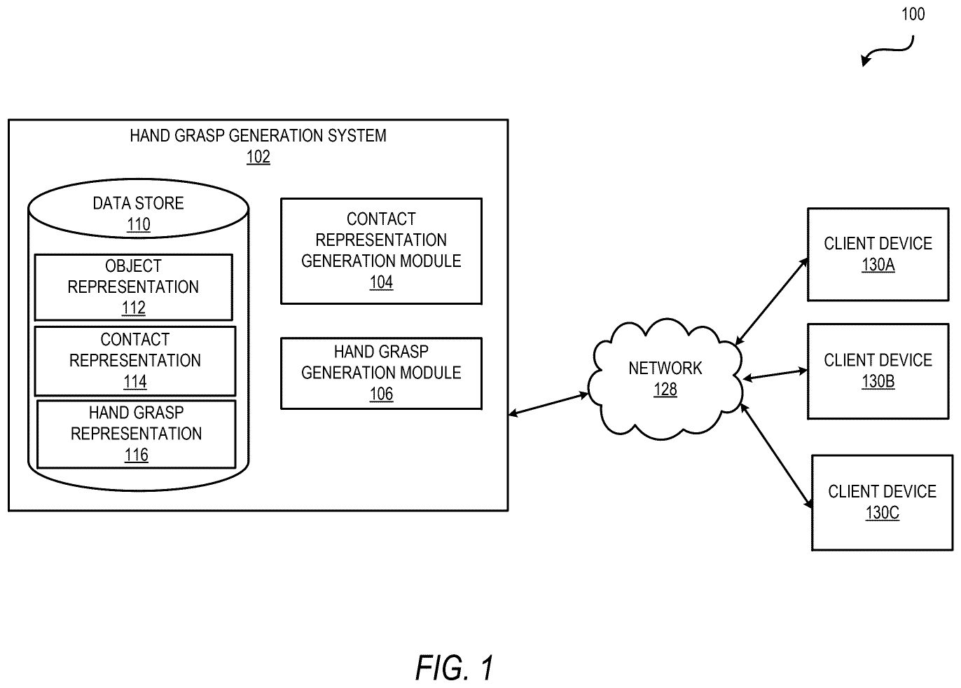

Referring now to the drawings, FIG. 1 depicts an example of a computing environment 100 in which a hand grasp generation system 102 generates a hand grasp representation for a digital object, according to certain embodiments of the present disclosure. In various embodiments, the computing environment 100 includes a hand grasp generation system 102 connected with client devices 130A, 130B, and 130C (which may be referred to herein individually as a client device 130 or collectively as the client devices 130) via a network 128. The network 128 may be a local-area network (“LAN”), a wide-area network (“WAN”), the Internet, or any other networking topology known in the art that connects the client device 130 to the hand grasp generation system 102.

The client device 130 is configured to transmit a request for generating a hand grasp representation 116 showing a hand grasping an object. The client device 130 provides an object representation 112 of a digital object, for example a point cloud representation of the object. The point cloud of the object can be pre-generated. In some examples, the computing environment 100 or the hand grasp generation system 102 can include a point cloud generator (not shown) to generate a point cloud representation of an object based on one or more images of the object.

The hand grasp generation system 102 includes a contact representation generation module 104. The contact representation generation module 104 is configured to generate a contact representation 114 for hand-object interaction. The contact representation 114 can include three components such as a contact map, a hand part map, and a direction map. The contact map includes contact probabilities of the points on the object contacted by a hand. The hand part map includes probabilities of each hand part contacting a point on the object. The direction map represents the orientation of the contact with respect to the hand part contacting a point on the object.

The hand grasp generation system 102 further includes a hand grasp generation module 106. The hand grasp generation module 106 is configured to generate a hand grasp representation 116 where a hand is grasping an object. A piecewise SDF model can be used to model different hand parts of a hand. An optimization algorithm can be implemented to determine hand poses and hand shapes based on the piecewise SDF hand model and the contact representation 114 for hand-object interaction generated by the contact representation generation module 104. The generated hand grasp representation can be provided to the client device 130 for display, for example virtual reality or augmented reality display, or for further process. In some examples, the hand grasp generation system 102 is a part of a greater system, for example, for making video animations. The generated hand grasp representation is provided to other components in the greater system to be incorporated into the animations or video games being made by the greater system.

The data store 110 is configured to store data processed or generated by the hand grasp generation system 102. Examples of the data stored in data store 110 include the object representation 112, the contact representation 114, and the hand grasp representation 116.

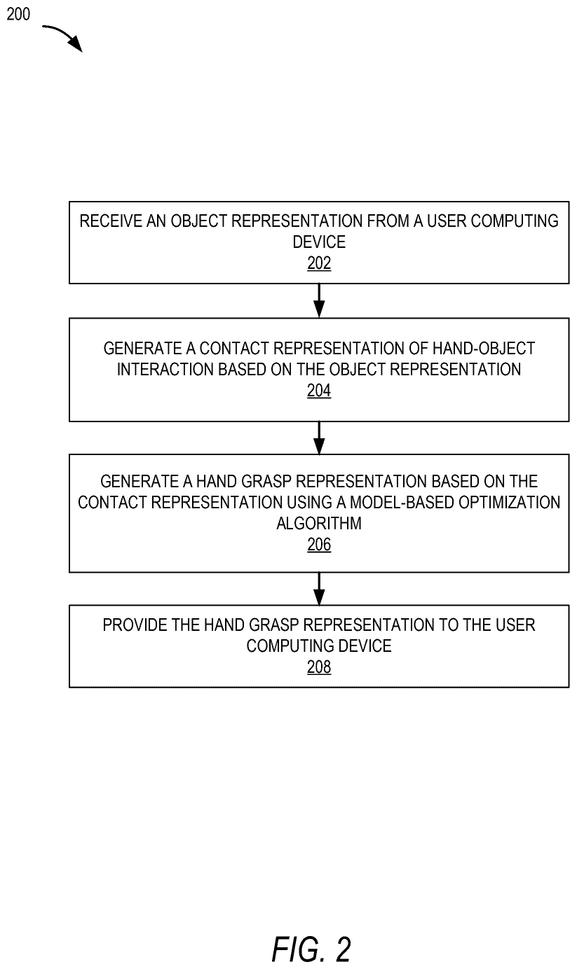

FIG. 2 depicts an example of a process 200 for generating a representation of a hand grasping an object, according to certain embodiments of the present disclosure. At block 202, a hand grasp generation system 102 receives an object representation 112 from a client device 130. The object representation 112 can be a 3D representation of an object, for example a point cloud representation of the object. The point cloud can be pre-generated. In some examples, the client device 130 generates a point cloud based on two or more object images taken from different directions, for example using photogrammetry techniques. In some examples, the hand grasp generation system 102 includes an object representation generation module, for example a point cloud generator, for generating the object representation using two or more object images received from the client device 130. In some examples, the object representation is a mesh model of the object.

At block 204, the hand grasp generation system 102 generates a contact representation 114 for hand-object interaction based on the object representation. The contact representation generation module 104 of the hand grasp generation system 102 can generate the contact representation 114 for hand-object interaction based on the object representation. The contact representation 114 for hand-object interaction can include three components, a contact map, a hand part map, and a direction map. The contact representation can be denoted as F=(C, P, D), where C is the contact map, P is the part map, and D is the direction map. The three components can be defined on a set of N object points O∈R^{N×3} sampled from the surface of the object representation 112.

The contact map C can include a contact probability of a point on the object point cloud being contacted by a hand grasping the object. In the contact map C∈R^{N×1}, each cᵢ∈C is between 0 and 1, representing the contact probability of an object point. The contact map illustrates which part of the object will likely be contacted by hand. However, relying solely on the contact map is insufficient for complex human-object interaction modeling due to ambiguities regarding how and where the hand touches the object. Thus, the contact representation also includes the hand part map and the direction map.

The hand part map P can include a categorical probability for a specific hand part (e.g., various fingertips or the palm) making contact with the object for grasping the object. For example, a hand object can be divided into B parts, and a hand part map can be denoted as P∈R^{N×B}, including multiple one-hot vectors. Each one-hot vector indicates the hand part label in {1, . . . , B} in contact with an object point O. Each value pᵢ∈P is taken as the closest hand part label in contact with an object point O.

The direction map D can include a vector on a unit sphere representing the orientation of the contact with respect to the hand part making the contact. To describe an arbitrary point on the surface of the hand part, the arbitrary point's direction to the part center is used. The direction map can be denoted as D∈R^{N×1}, and dᵢ∈D represents the direction of a contact point with respect to a hand part b∈B. Each hand part can be considered as a unit sphere, and the contact direction could be any ray shooting from the part center to the sphere surface. Given the direction dᵢ, the contact point location in part b could be uniquely determined by searching along the ray, for example until corresponding SDF equals 0 based on the SDF hand model.

In some examples, the hand grasp generation system 102 determines a contact map based on the object representation using a first conditional variational autoencoder (CVAE) model of a sequence of CVAE models. the hand grasp generation system 102 then determines a hand part map including indications of hand part contacting the object for grasping the object based on the contact map and the object representation using a second CVAE model of the sequence of CVAE models. The hand grasp generation system 102 then determines a direction map based on the hand part map and the object representation using a third CVAE model of the sequence of CVAE models.

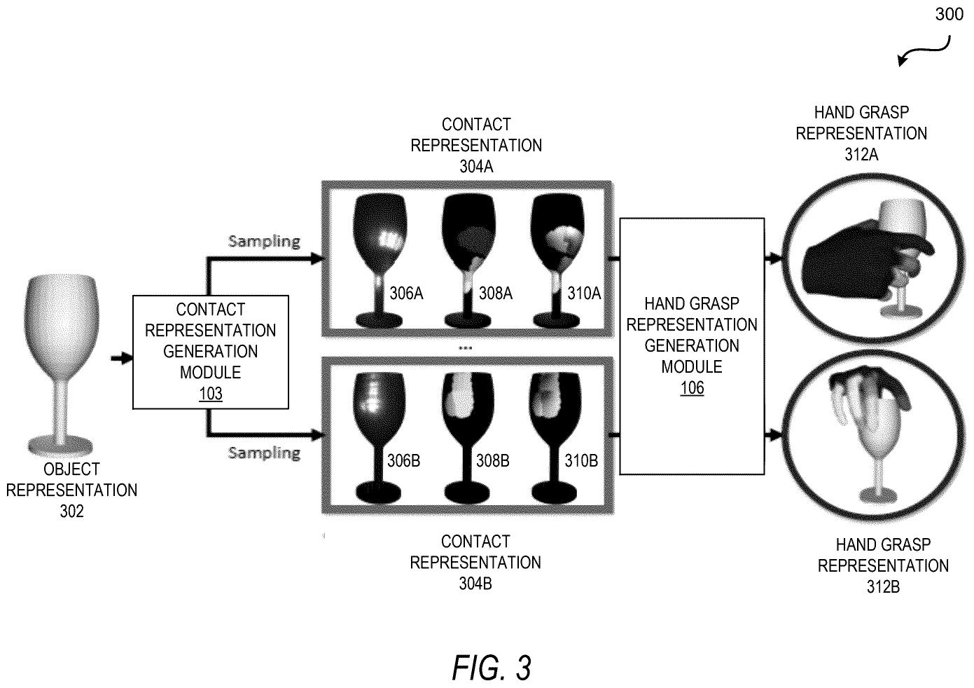

In some examples, object features are extracted from the point cloud representation of the object. The object features are sampled object points. Given the sampled object points O as input, the contact representation generation module 104 of the hand grasp generation system 102 can implement a conditional generative framework to infer possible object-centric contact representations F from the underlying distribution p(F|O). In some examples, the conditional generative framework is a point-based network that operates on a sampled point cloud representing an object. For example, the distribution p(F|O) is modeled sequentially using a sequence of CVAE models, which can model multi-modal uncertainty. The sequence of CVAE models can include three sets of encoders and decoders corresponding to the three components of the contact representation: that is, a contact encoder and a contact decoder for determining the contact map, a part encoder and a part decoder for determining the hand part map, and a direction encoder and a direction decoder for determining the direction map. Even though in FIG. 3, a sequence of CVAE models is implemented to generate the contact representation, other suitable generative models can also be used, for example diffusion models. The joint distribution of the contact representation F=(C, P, D) can be factorized into a product of three conditional probabilities, as shown in Equation (1).

$$p ( F \vert O ) = p ( D \vert P , O ) p ( P \vert C , O ) p ( C \vert O ) \qquad ( 1 )$$

The contact map C is conditioned on object input O; the part map P is additionally conditioned on contact map C; and the direction map is additionally conditioned on part map P. The sequential structure guarantees that the three generated maps are consistent with each other by decomposing the complicated contact sampling into the conditional generation of each component. Existing decomposition methods include joint modeling and separate modeling. Joint modeling uses a shared encoder to encode the three maps and a shared decoder to decode them jointly. Separate modeling encodes and decodes each component independently, using three separate encoders and decoders for the three maps. However, decomposition by these two existing methods does not maintain consistency among the three components, failing to yield physically plausible grasp, with large penetrations, decreased contact ratios, or higher simulation displacements. By comparison, with the sequence of CVAE models, the generated outcomes are internally consistent and exhibit substantial diversity.

Each component in Equation (1) can be controlled by a latent code z randomly sampled from a Gaussian distribution of a latent space generated by a corresponding encoder. The complete hand information can be recovered from a sampled contact map Ĉ, a sampled hand part map \hat{P}, and a sampled direction map \hat{D}, which can be obtained as described in Equations (2)-(4) below. In Equations (2)-(4), z_{c}, zₚ, and z_{d} are sampled latent codes from corresponding contact latent space, part latent space, and the direction latent space generated by corresponding encoders, and [symbol] _{c}, [symbol] ₚ, and [symbol] _{d} denote the conditional decoders for generating the contact map, part map and direction map.

$$\hat{C} = {𝒢}_{c} ( {z}_{c} ; O ) \qquad ( 2 )$$

$$\hat{P} = {𝒢}_{p} ( {z}_{p} ; \hat{C} ; O ) \qquad ( 3 )$$

$$\hat{D} = {𝒢}_{d} ( {z}_{d} ; \hat{P} ; O ) \qquad ( 4 )$$

At block 206, the hand grasp generation system 102 generates a hand grasp representation 116 with respect to the object based on the contact representation 114 using a model-based optimization algorithm.

In order to convert the contact representation into a corresponding articulated hand grasp, a hand model is needed. The hand model can be a mesh model or a piecewise SDF model. In this example, a piecewise SDF model converted from a MANO model (a hand model with articulated and non-rigid deformation) is used to represent different hand parts of a hand. A piecewise SDF hand model is compatible with the contact representation 114 obtained at block 204. The piecewise SDF hand model can partition a hand into B parts and use a piecewise SDF to represent each part. The overall piecewise SDF hand model includes part pose parameters corresponding to different hand parts and a global shape parameter corresponding to the hand. A part pose parameter is an axis angle in a global coordinate system transformed from the hand part's local coordinate frame.

Given a hand part b, the signed distance from an object point Oᵢ to the surface of the hand part can be expressed in Equation (5) and the direction of the object point with respect to the hand part can be expressed in Equation (6), where T_{b} is the transformation from a hand part b's local coordinate frame to a global coordinate frame, θ_{b} is an axis angle for hand part b, and β is a global shape vector for the hand.

$${SDF}_{b} ( {T}_{b}^{- 1} {o}_{i} ; β ) = {SDF}_{b} ( {T ( {θ}_{b} )}^{- 1} {o}_{i} ; β ) \qquad ( 5 )$$

$${d}_{i} = \frac{{T}_{b}^{- 1} {O}_{i}}{‖ {T}_{b}^{- 1} {O}_{i} ‖} \qquad ( 6 )$$

The hand grasp generation module 106 can implement an optimization algorithm to infer an SDF hand model, based on the sampled points O and the contact representation F (C, P, D) obtained at block 204. The optimization object can be described in Equation (7).

$$optimization objective = {min}_{θ , β} {λ}_{c} {ℒ}_{c} + {λ}_{d} {ℒ}_{d} + {λ}_{p} {ℒ}_{p} + {λ}_{r} {ℒ}_{r} \qquad ( 7 )$$

In Equation (7), [symbol] _{c} denotes the contact map loss as expressed in Equation (8). The SDF of a point in hand part b can be optimized to be close to 0, driving the hand part b to touch the contact location.

$${ℒ}_{c} = \hat{C} {\sum }_{b = 1}^{B} {\hat{P}}_{b} \cdot \vert {SDF}_{b} \vert \qquad ( 8 )$$

In Equation (7), [symbol] _{d} denotes the direction loss as expressed in Equation (9), where Wc is a weight parameter. The direction loss [symbol] _{d} can be optimized to minimize the difference between the point direction of hand part b and the predicted direction.

$${ℒ}_{d} = {W}_{C} ( 1 - cos ( D , \hat{D} ) ) \qquad ( 9 )$$

In Equation (7), [symbol] ₚ denotes the penetration loss as expressed in Equation (10). The penetration loss [symbol] ₚ can be minimized to prevent object sampled points from being inside the hand.

$${ℒ}_{p} = {\sum }_{b = 1}^{B} - max ( {SDF}_{b} , 0 ) \qquad ( 10 )$$

In Equation (7), [symbol] ᵣ denotes the regularization term of the piecewise SDF hand model as expressed in Equation (11). The regularization term [symbol] ᵣ can be optimized to prevent the piecewise SDF hand model from being too complex.

$${ℒ}_{r} = {‖ θ ‖}^{2} + {‖ β ‖}^{2} \qquad ( 11 )$$

In some examples, the hand grasp generation module 106 can implement an Adam optimization algorithm to achieve the optimization objective in equation (7) and obtain the hand pose parameters θ and the shape parameter β for generating a hand grasp representation. In some examples, the hand grasp generation module 106 can implement a two-stage optimization strategy. In the first stage, the global pose of the hand can be optimized. In the second stage, the hand's global pose is fixed, and the hand's pose parameters and the shape parameter are then optimized. The Adam optimization algorithm can be implemented at both stages.

The three components in the contact representation are unique and critical in achieving optimal performance in generating hand grasp representations. Without the guidance of the part map, the piecewise SDF hand model may not be able to generate a coherent grasp, leading to consistently higher penetrations. Incorporating the direction map can improve contact and stability. In some examples, a MANO model can be used to model a hand for generating the hand grasp representation. Both the MANO model and the piecewise SDF model can achieve similar physical quality with the assistance of all three maps. However, employing the SDF model can better capture find-grained hand poses, resulting in enhanced diversity and more stable outcomes.

At block 208, the hand grasp generation system 102 provides the hand grasp representation 116 to the client device 130. The hand grasp representation can be displayed in a graphical user interface (GUI) of the client device 130. The hand grasp representation 116 depicts a hand grasping the object. The hand grasp representation 116 can be manipulated to show different perspectives. Multiple different hand grasp representations can be generated with respect to one object.

The hand grasp generation system 102 in the present disclosure is not limited to generating hand grasp representations for hand-object interaction. By substituting the object for another hand, the hand grasp generation system 102 can synthesize two-hand interactions. For example, the sequence of CVAE models can be trained using a training dataset associated with hand-hand interactions. The sequence of CVAE models can be used to generate a contact representation for hand-hand interactions. The same hand model and optimization algorithm as described at block 206 can be used to generate hand poses. For example, by taking the left hand as input, corresponding right-hand poses can be generated.

FIG. 3 depicts an example of a diagram for generating a hand grasp representation, according to certain embodiments of the present disclosure. The object representation 302 can be a three-dimensional (3D) point cloud representing a 3D object. The object representation 302 is a conditional input of the contact representation generation module 104, generally as described in FIG. 1. The contact representation generation module 104 can initially model an underlying distribution of contact maps. A user can sample the underlying distribution of contact maps, for example to obtain multiple sampled contact maps A, B, . . . , N. The sampled contact maps can correspond to different object features. The sampled contact maps are used as additional conditioning inputs for the contact representation generation module 104 to generate corresponding hand part maps. Further, the sampled contact maps and the corresponding hand part maps are used to generate corresponding direction maps. In this example, a contact map 306A can be sampled from an underlying distribution of contact maps generated by the contact representation generation module 104, and used as an input for generating a hand part map 308A, which can in turn be used as an input to generate a direction map 310A. The sampled contact map 306A, corresponding hand part map 308A, and corresponding direction map 310A are the three components of the contact representation 304A for grasping the object illustrated by the object representation 302. The contact representation 304A is provided to the hand grasp generation module 106 for generating a hand grasp representation 312A. Alternatively, or additionally, a different contact map 306B can be sampled from the underlying distribution of contact maps and used to generate corresponding hand part map 308B and direction map 310B. Thus, a different contact representation 304B can be obtained. The contact representation 304B can be used to generate a corresponding hand grasp representation 312B.

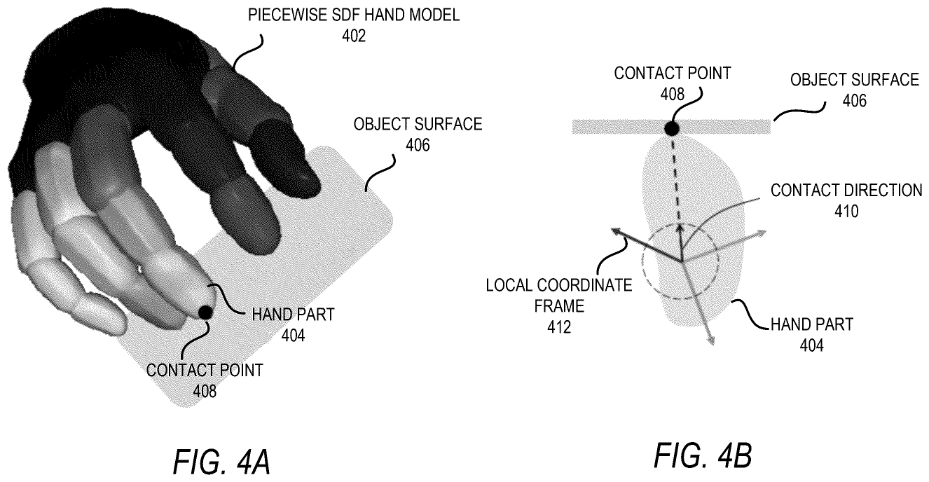

FIG. 4A depicts an example of a hand part in a piecewise SDF hand model contacting an object surface, according to certain embodiments of the present disclosure. FIG. 4B depicts an example of a contact direction of the hand part in FIG. 4A, according to certain embodiments of the present disclosure. In FIG. 4A, a piecewise SDF hand model 402 represents a hand object partitioned into 16 hand parts. A hand part 404 is contacting an object surface 406 at contact point 408. FIG. 4B illustrates the contact direction 410 for the hand part 404 contacting the contact point 408. The contact direction 410 is a unit vector from the center of the hand part 404 towards the contact point 408, in the local coordinate frame 412. The origin of the local coordinate frame 412 is at the center of the hand part 404.

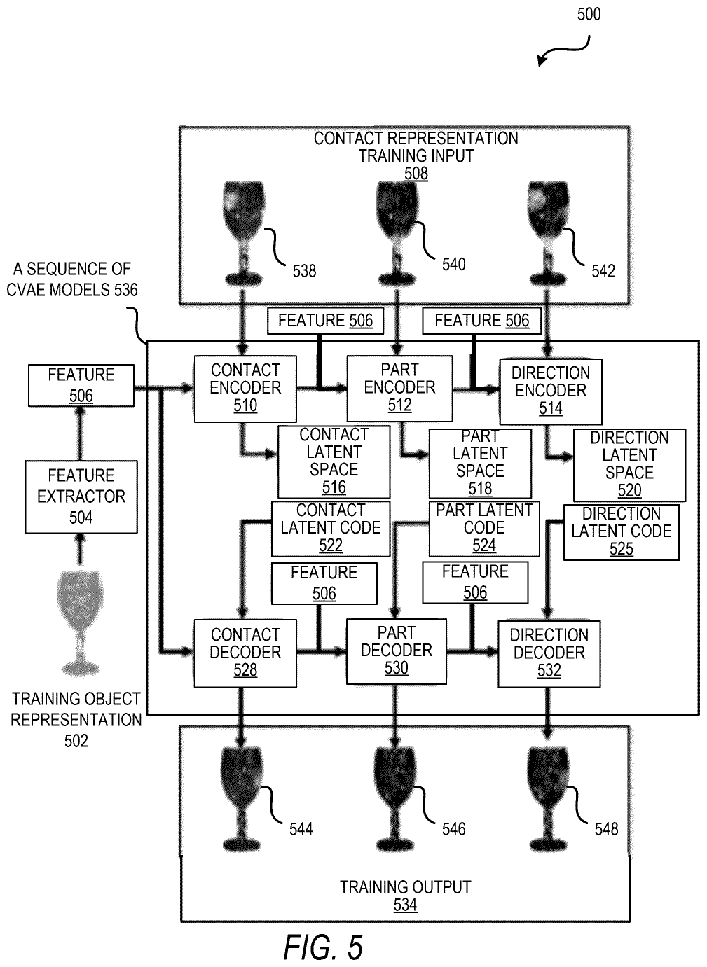

FIG. 5 depicts an example of a training process for a sequence of CVAE models, according to certain embodiments of the present disclosure. A feature extractor 504 can extract object features 506 from a training object representation 502 and provide the extracted object features 506 to a sequence of CVAE models 536 for training. The feature extractor 504 can be a PointNet++ algorithm, for example a PointNet++ single scale grouping network. In FIG. 5, the sequence of CVAE models 536 includes three sets of encoders and decoders, for example a set of contact encoder 510 and contact decoder 528, a set of part encoder 512 and part decoder 530, and a set of direction encoder 514 and direction decoder 532.

A ground truth contact representation 508 corresponding to the training object representation 502 is provided to the sequence of CVAE models 536 as training input. The ground truth contact representation 508 includes a ground truth contact map 538, a ground truth hand part map 540, and a ground truth direction map input 542. The object features 506 and the ground truth contact map 538 are used to train the contact encoder 510. The contact encoder 510 can be a neural network trained to generate a contact latent space 516 representing contact points in a variational distribution, for example a Gaussian distribution, based on the ground truth contact map 538. The contact decoder 528 can be trained with object features 506 and contact latent code 522 sampled from a posterior Gaussian distribution of contact points in the contact latent space 516 to generate a contact map output 544.

The object features 506 and the ground truth hand part map 540 are used to train the part encoder 512. The part encoder 512 can be a neural network trained to generate a part latent space 518 representing contact hand parts in a variational distribution, for example a Gaussian distribution, based on the ground truth hand part map 640. The part decoder 530 can be trained with the object features 506 and the part latent code 524 sampled from a posterior Gaussian distribution of contact hand parts in the part latent space 518 to generate a hand part map output 546.

The object features 506 and the ground truth direction map input 542 are used to train the direction encoder 514. The direction encoder 514 can be a neural network trained to generate a latent space representing contact directions in a variational distribution, for example a Gaussian distribution, based on the ground truth direction map input 542. The direction decoder 532 can be trained with the object features 506 and the direction latent code 526 sampled from a posterior Gaussian distribution of contact directions in the direction latent space 520 to generate a direction map output 548.

The sequence of the CVAE models 536 can be trained jointly using a teacher forcing training algorithm to minimize a total loss [symbol] of the sequence of CVAE models 536, including a reconstruction term and a KL regularization term, as expressed in Equation (12).

$$ℒ = {ℒ}_{rec} + {λ}_{KL} {ℒ}_{KL} \qquad ( 12 )$$

The reconstruction term [symbol] _{rec} can be defined as shown in Equation (13), where [symbol] _{CE} is the standard cross-entropy loss between the predicted part label \hat{P} and ground truth P, [symbol] _{d} computes the cosine similarity between the ground truth direction dᵢ and predicted direction \hat{d}ᵢ for each point. All losses can be computed per-point and weighted by W_{c}=C+δ, where C∈[0, 1] is the ground truth contact map value and δ is a default weight for non-contacted points.

$${ℒ}_{rec} = {W}_{C} ( \vert C - \hat{C} \vert + {λ}_{p} {ℒ}_{CE} ( P , \hat{P} ) + {λ}_{d} {ℒ}_{d} ( D , \hat{D} ) ) \qquad ( 13 )$$

The KL regularization [symbol] _{KL} regularizes a latent space close to normal distribution [symbol] (0, I), as shown in Equation (14). The total KL loss can include regularization from each latent space, as shown in Equation (15).

$${ℒ}_{KL} ( μ , \sum ) = KL [ ( μ , {\sum }^{2} ) ‖ ( 0 , I ) ] \qquad ( 14 )$$

$${ℒ}_{KL} = {ℒ}_{KL} ( {μ}_{c} , {\sum }_{c} ) + {ℒ}_{KL} ( {μ}_{p} , {\sum }_{p} ) + {ℒ}_{KL} ( {μ}_{d} , {\sum }_{d} ) \qquad ( 15 )$$

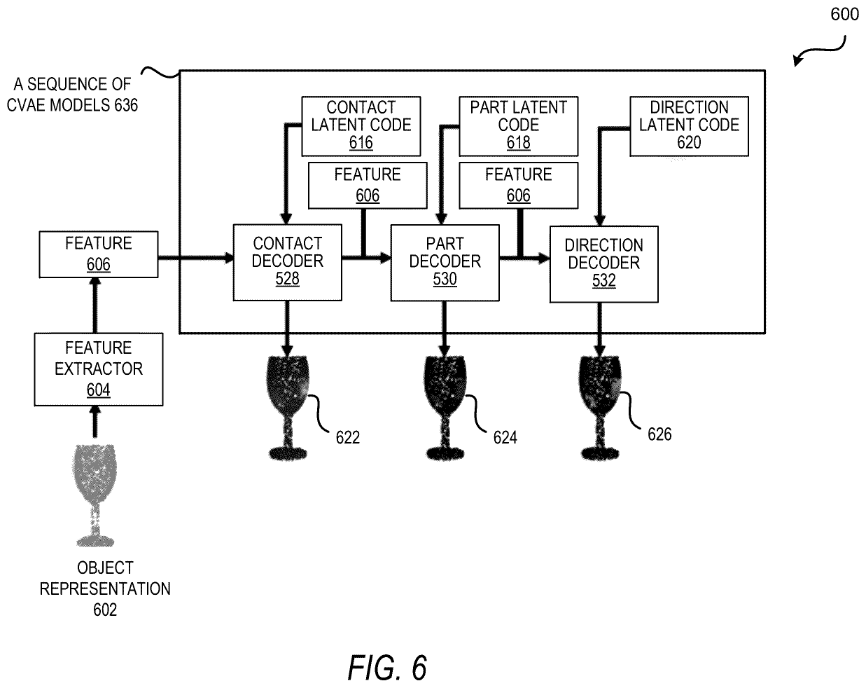

FIG. 6 depicts an example of an inference process of generating a contact representation using a sequence of CVAE models trained in FIG. 5, according to certain embodiments of the present disclosure. Object features 606 can be extracted from an object representation 602 using a feature extractor 604. Similar to the feature extractor 504, feature extractor 604 can be a PointNet++ algorithm, for example a PointNet++ single scale grouping network. The object features 606 are provided to a sequence of CVAE models 536, which has been trained as described in FIG. 5. During the inference phase, only the decoders are used to decode the contact map, hand part map, and the direction map from the object features 608. For example, the contact decoder 528 can generate a contact map 622 using the object features 606 and contact latent code 616 sampled from a prior Gaussian distribution (e.g., normal distribution) of contact points in the contact latent space 516, which is generated during the training phase by the contact encoder 510 as described in FIG. 5. The part decoder 530 can generate a hand part map 624 using the object features 606 and part latent code 618 sampled from a prior Gaussian distribution (e.g., normal distribution) of hand parts in the part latent space 518, which is generated by the part encoder 512 during the training phase as described in FIG. 6. The direction decoder 532 can generate a direction map 626 using the object features 606 and direction latent code 620 sampled from a prior Gaussian distribution (e.g., normal distribution) of contact directions in the direction latent space 520, which is generated by the direction encoder 514 during the training phase as described in FIG. 5. The randomly sampled latent codes in the contact representation generation provide diversity in the hand grasp representation, which is generated based on the contact representation.

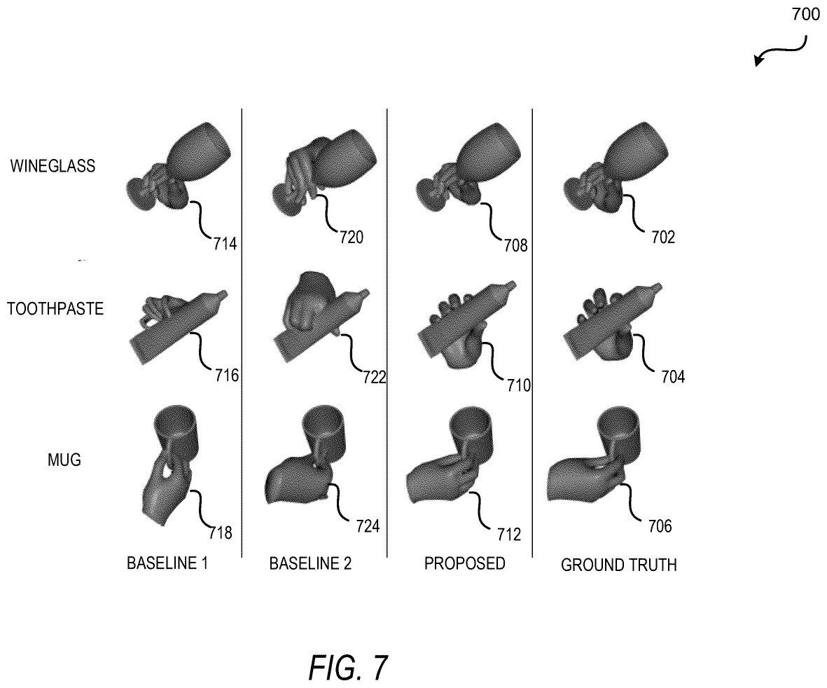

FIG. 7 depicts an example of a comparison between recovered hand grasp representations using different methods and ground truth representations, according to certain embodiments of the present disclosure. Ground truth hand grasp representations with respect to three objects are provided. For example, a hand grasp representation 702 shows a hand grasping a wineglass, a hand grasp representation 704 shows a hand grasping a toothpaste tube, and a hand grasp representation 706 shows a hand grasping a mug. The proposed contact representation modeling and hand grasp optimization procedure in the present disclosure can reconstruct the ground truth hand grasp representations with respect to the three objects to generate three hand grasp representations 708, 710, and 712. Meanwhile, baseline method 1 is also used to reconstruct the ground truth hand grasp representations to generate hand grasp representations 714, 716, and 718. The baseline method 1 is an existing method using contact maps on both the hand and object to fine hand pose. In addition, baseline method 2 is also used to reconstruct the ground truth hand grasp representations to generate hand grasp representations 720, 722, and 724. The baseline method 2 is an existing method using binary contact labels on the object's surface and hand correspondence on the MANO mesh to represent contacts. The hand pose is optimized from scratch in all three methods (e.g., the proposed in the present disclosure, baseline method 1, and baseline method 2) for all the three objects (e.g., wineglass, toothpaste tube, and mug). As shown in FIG. 7, both baseline method 1 and baseline method 2 exhibit failures in certain cases, whereas the proposed method in the present disclosure manages to achieve the closest reconstruction to the ground truth. For example, both baseline method 1 and baseline method 2 are unable to accurately recover the ground truth hand pose due to the ambiguity of their respective representations. Baseline method 1, despite having access to the ground truth hand and object contact maps, has poor performance in determining the specific hand-part that should establish contact with a given contact location on the object, for example the hand grasp representation 716. Baseline method 2 shows comparatively better performance due to the richer contact information from hand-object correspondences. However, the contact location is sparse, the hand pose is not uniquely defined, and the contact direction can also vary, for example the hand grasp representations 720 and 722.

TABLE 1
Metrics Comparison for Hand Grasp
Reconstruction by Different Methods

| Method | EPE (cm) | AUC | F-score @ 5 mm | F-score @ 15 mm |
|---|---|---|---|---|
| Baseline 1 | 7.00 | 0.26 | 0.24 | 0.50 |
| Baseline 2 | 3.44 | 0.51 | 0.39 | 0.72 |
| Proposed | 1.49 | 0.77 | 0.55 | 0.91 |

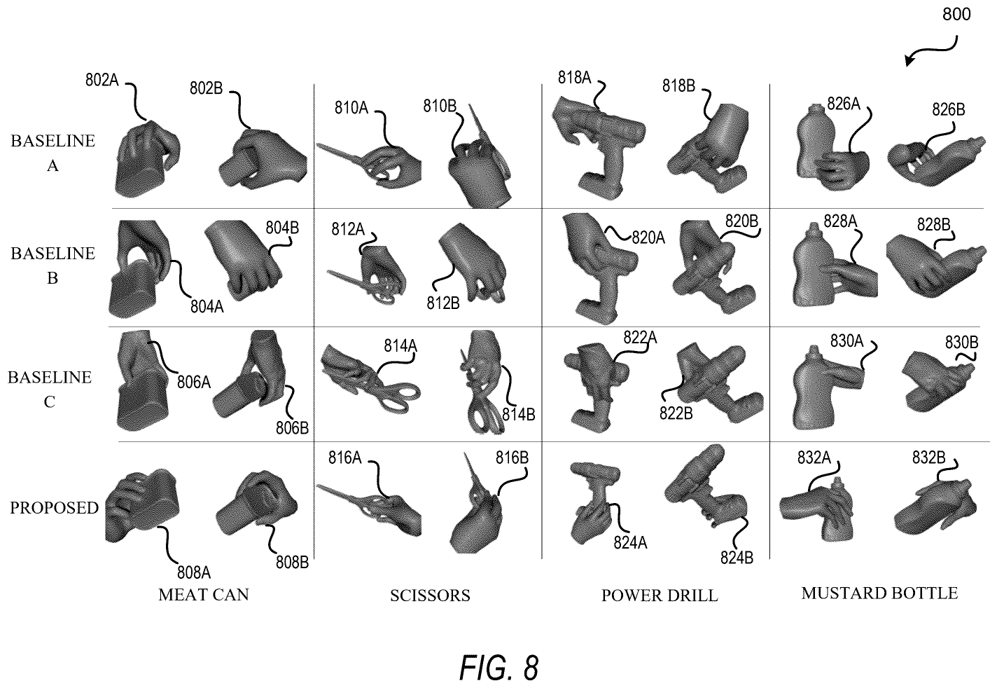

Table 1 shows a comparison of various metrics associated with hand grasp representations recovered using different methods as illustrated in FIG. 8, according to certain embodiments of the present disclosure. Mesh endpoint error (EPE) measures the average Euclidean distance between the hand vertices of a recovered representation and the ground truth representation. It can be seen in Table 1, the EPE value corresponding to the proposed method 1.49 cm is the lowest, meaning the hand vertices in the hand grasp representation recovered by the proposed method is the closest to the ground truth, compared with those recovered by the baseline 1 and baseline 2 methods. Mesh AUC measures the percentage of correctly reconstructed vertices (e.g., vertices within 5 cm are considered correct). In Table 1, the Mesh area under the curve (AUC) value corresponding to the proposed method 0.77 is the highest, meaning the percentage of correctly reconstructed vertices in the hand grasp representation recovered using the proposed method is higher than those recovered using baseline 1 and baseline 2 methods. Mesh F-Score calculates the harmonic mean of recall and precision between two meshes given a distance threshold. In Table 1, F-scores at 5 mm and 15 mm are provided. The F-scores corresponding to the proposed method are the highest, 0.55@5 cm and 0.91@15 mm, meaning the proposed method has the best precision and recall, compared to baseline 1 and baseline 2 methods.

FIG. 8 depicts an example of a comparison of hand grasp representations generated by the proposed method and baseline grasp generation methods, according to certain embodiments of the present disclosure. The sequence of CVAE models in the proposed methods can be trained using a subset of a first dataset (e.g., GRAB dataset), and the grasp synthesis performance can be tested using another subset of the first dataset not overlapping with the subset used for training. Alternatively, the grasp synthesis performance can be tested using a second dataset (HO3D dataset) different from the first dataset (e.g., not in the same domain). In FIG. 8, the baseline methods and the proposed methods are all trained using the GRAB dataset, and hand grasp representations are generated using the HO3D dataset. Baseline A method is GraspTTA, baseline B method is GrabNet, and baseline C method is HALO. Each method generates a hand grasp representation for a meat can, a pair of scissors, a power drill, and a mustard bottle. Each hand grasp representation includes two views. For example, with respect to a meat can, view 802A and view 802B correspond to a hand grasp representation generated by the baseline A method, View 804A and view 804B correspond to a hand grasp representation generated by the baseline B method, view 806A and view 806B correspond to a hand grasp representation generated by the baseline C method, and view 808A and view 808B correspond to a hand grasp representation generated by the proposed method of the present disclosure. It can be seen that the baseline method A and baseline B method produce nearly identical grasps for different objects, resulting in poor diversity in terms of contact locations and grasp poses. Hand grasp representations generated using the baseline C method have better diversity in terms of contact locations and grasp poses, but show high penetration, low contact, and poor stability. The hand grasp representations generated using the proposed method achieve notably lower penetration, higher contact ratio, better stability, and greater diversity.

TABLE 2
Metrics Comparison for Hand Grasp Representations
Generated by Different Methods

| | Penetration | Contact | Simulation | | Cluster |
|---|---|---|---|---|---|
| Method | Volume | Ratio | Displacement | Entropy | Size |
| Baseline A | 7.37 | 0.76 | 5.34 | 2.70 | 1.43 |
| Baseline B | 15.50 | 0.99 | 2.34 | 2.80 | 2.06 |
| Baseline C | 25.84 | 0.97 | 3.02 | 2.81 | 4.87 |
| Proposed | 9.96 | 0.97 | 2.70 | 2.81 | 5.04 |

Table 2 shows a comparison of various metrics between hand grasp representations generated using different methods as illustrated in FIG. 8, according to certain embodiments of the present disclosure. The generated hand-object interpenetration volume and contact ratio metrics can be used to assess physical plausibility. The interpenetration volume can be calculated by voxelizing the meshes into 1 mm³ cubes and measuring overlapping voxels. Contact ratio calculates the proportion of grasps that are in contact with objects. For grasp stability assessment, the object and the predicted grasp can be placed into a simulator to measure the average Simulation Displacement of the object's center of mass under the influence of gravity. Diversity in generated hand grasps can be evaluated by first clustering generated grasps into 20 clusters using K-means and then measuring the Entropy of cluster assignments and the average Cluster Size. Higher entropy and cluster size values indicate better diversity. It can be seen in Table 1, the hand grasp representation generated by the proposed method of the present disclosure has low penetration volume (e.g., 9.96), high contact ratio (e.g., 0.97), and low simulation displacement (e.g., 2.70), all these three metrics are close to the best, compared to those corresponding to hand grasp representations generated by the baseline methods. Meanwhile, the entropy (e.g., 2.81) and the cluster size (e.g., 5.04) are the highest, indicating the highest diversity in the hand grasp representation generated by the proposed method. Besides, the hand grasp representations can also be evaluated by human evaluators, with respect to the naturalness and stability. The hand grasp representation generated by the proposed method shows higher naturalness and stability to human evaluators, even though lower than the ground truth grasps.

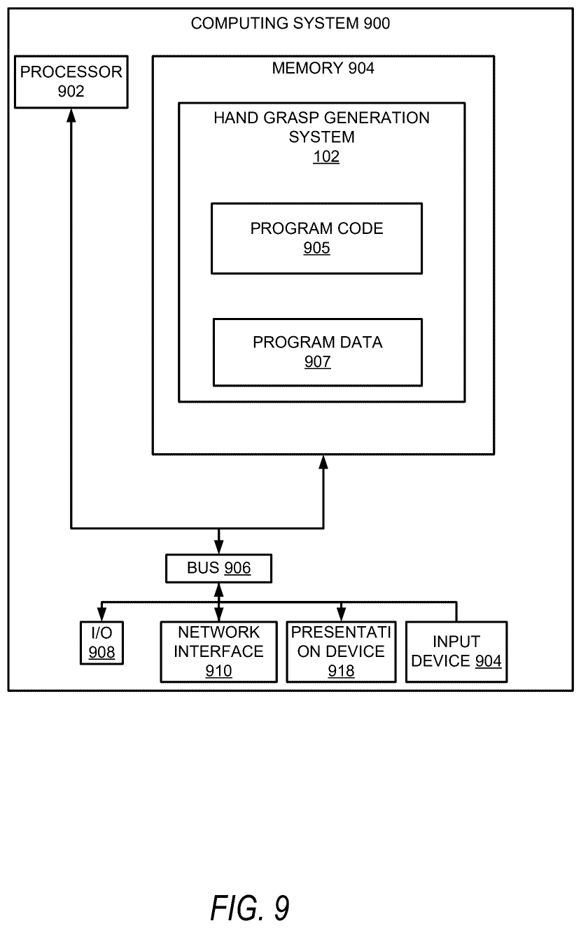

Any suitable computing system or group of computing systems can be used for performing the operations described herein. For example, FIG. 9 depicts an example of the computing system 900 for implementing certain embodiments of the present disclosure. The implementation of computing system 900 could be used to implement the hand grasp generation system 102. In other embodiments, a single computing system 900 having devices similar to those depicted in FIG. 9 (e.g., a processor, a memory, etc.) combines the one or more operations depicted as separate systems in FIG. 1.

The depicted example of a computing system 900 includes a processor 902 communicatively coupled to one or more memory devices 904. The processor 902 executes computer-executable program code stored in a memory device 904, accesses information stored in the memory device 904, or both. Examples of the processor 902 include a microprocessor, an application-specific integrated circuit (“ASIC”), a field-programmable gate array (“FPGA”), or any other suitable processing device. The processor 902 can include any number of processing devices, including a single processing device.

A memory device 904 includes any suitable non-transitory computer-readable medium for storing program code 905, program data 907, or both. A computer-readable medium can include any electronic, optical, magnetic, or other storage device capable of providing a processor with computer-readable instructions or other program code. Non-limiting examples of a computer-readable medium include a magnetic disk, a memory chip, a ROM, a RAM, an ASIC, optical storage, magnetic tape or other magnetic storage, or any other medium from which a processing device can read instructions. The instructions may include processor-specific instructions generated by a compiler or an interpreter from code written in any suitable computer-programming language, including, for example, C, C++, C#, Visual Basic, Java, Python, Perl, JavaScript, and ActionScript.

The computing system 900 executes program code 905 that configures the processor 902 to perform one or more of the operations described herein. Examples of the program code 905 include, in various embodiments, the application executed by the hand grasp generation system 102, or other suitable applications that perform one or more operations described herein. The program code may be resident in the memory device 904 or any suitable computer-readable medium and may be executed by the processor 902 or any other suitable processor.

In some embodiments, one or more memory devices 904 stores program data 907 that includes one or more datasets and models described herein. Examples of these datasets include extracted images, feature vectors, aesthetic scores, processed object images, etc. In some embodiments, one or more of data sets, models, and functions are stored in the same memory device (e.g., one of the memory devices 904). In additional or alternative embodiments, one or more of the programs, data sets, models, and functions described herein are stored in different memory devices 904 accessible via a data network. One or more buses 906 are also included in the computing system 900. The buses 906 communicatively couples one or more components of a respective one of the computing system 900.

In some embodiments, the computing system 900 also includes a network interface device 910. The network interface device 910 includes any device or group of devices suitable for establishing a wired or wireless data connection to one or more data networks. Non-limiting examples of the network interface device 910 include an Ethernet network adapter, a modem, and/or the like. The computing system 900 is able to communicate with one or more other computing devices (e.g., client device 130) via a data network using the network interface device 910.

The computing system 900 may also include a number of external or internal devices, an input device 920, a presentation device 918, or other input or output devices. For example, the computing system 900 is shown with one or more input/output (“I/O”) interfaces 908. An I/O interface 908 can receive input from input devices or provide output to output devices. An input device 920 can include any device or group of devices suitable for receiving visual, auditory, or other suitable input that controls or affects the operations of the processor 902. Non-limiting examples of the input device 920 include a touchscreen, a mouse, a keyboard, a microphone, a separate mobile computing device, etc. A presentation device 918 can include any device or group of devices suitable for providing visual, auditory, or other suitable sensory output. Non-limiting examples of the presentation device 918 include a touchscreen, a monitor, a speaker, a separate mobile computing device, etc.

Although FIG. 9 depicts the input device 920 and the presentation device 918 as being local to the computing device that executes the hand grasp generation system 102, other implementations are possible. For instance, in some embodiments, one or more of the input device 920 and the presentation device 918 can include a remote client-computing device that communicates with the computing system 900 via the network interface device 910 using one or more data networks described herein.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computing system from a general purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alternatives to, variations of, and equivalents to such embodiments. Accordingly, it should be understood that the present disclosure has been presented for purposes of example rather than limitation, and does not preclude the inclusion of such modifications, variations, and/or additions to the present subject matter as would be readily apparent to one of ordinary skill in the art.

What is claimed is:

1. A method performed by one or more processing devices, comprising:
receiving a representation of an object from a client device;
generating a contact representation for hand-object interaction based on the representation of the object, wherein the contact representation comprises a contact map indicating contact points on the representation of the object, a hand part map indicating hand parts contacting the object, and a direction map comprising contact directions of the hand parts contacting the object, wherein generating the contact representation comprises:
determining the contact map based on the representation of the object;
determining the hand part map based on the contact map and the 9 representation of the object; and
determining the direction map based on the hand part map and the representation of the object; and
generating a hand grasp representation with respect to the object based on the contact representation using a model-based optimization algorithm; and
providing the hand grasp representation to the client device.

2. The method of claim 1, wherein the representation of the object is a point cloud.

3. The method of claim 1, further comprising generating the contact representation for hand-object interaction based on the representation of the object using a sequence of conditional variational autoencoder (CVAE) models.

4. The method of claim 3, wherein generating a contact representation for hand-object interaction based on the representation of the object further comprises:
determining the contact map for grasping the object based on a plurality of object features using a first CAVE model of the sequence of CAVE models;
determining the hand part map for grasping the object based on the contact map and the plurality of object features using a second CAVE model of the sequence of CAVE models; and
determining the direction map for grasping the object based on the hand part map and the plurality of object features using a third CAVE model of the sequence of CAVE models.

5. The method of claim 4, further comprising extracting the plurality of object features using a PointNet++ algorithm.

6. The method of claim 4, wherein the first CAVE model comprises a contact encoder and a contact decoder, wherein the second CAVE model comprises a part encoder and part decoder, and wherein the third CAVE model comprises a direction encoder and a direction decoder.

7. The method of claim 1, wherein the representation of the hand grasping the object is based on a part-wise Signed Distance Function (SDF) hand model, wherein the representation of the hand grasping the object comprises multiple pose parameters corresponding to multiple hand parts contacting the object and a shape parameter corresponding to the hand.

8. The method of claim 7, wherein generating a representation of a hand grasping the object based on the contact representation using a model-based optimization algorithm comprises determining the multiple pose parameters corresponding to multiple hand parts grasping the object and the shape parameter corresponding to the hand grasping the object by minimizing a total loss function related to the contact representation using the an optimization algorithm.

9. The method of claim 8, wherein the total loss function comprises a contact map loss, a direction loss, a penetration loss, and a regularization loss.

10. The method of claim 8, wherein the optimization algorithm comprises an Adam optimization algorithm.

11. A system, comprising:
a memory component;
a processing device coupled to the memory component, the processing device to perform operations comprising:
receiving a representation of an object from a client device;
generating a contact representation for hand-object interaction based on the representation of the object, wherein the contact representation comprises a contact map indicating contact points on the representation of the object, a hand part map indicating hand parts contacting the object, and a direction map comprising contact directions of the hand parts contacting the object, wherein generating the contact representation comprises:
determining the contact map based on the representation of the object;
determining the hand part map based on the contact map and the representation of the object; and
determining the direction map based on the hand part map and the representation of the object; and
generating a hand grasp representation with respect to the object based on the contact representation using a model-based optimization algorithm; and
providing the hand grasp representation to the client device.

12. The system of claim 11, wherein the representation of the object is a point cloud.

13. The system of claim 11, wherein the processing device is to perform further operations comprising:
generating the contact representation for hand-object interaction based on the representation of the object using a sequence of conditional variational autoencoder (CVAE) models, comprising:
determining the contact map for grasping the object based on a plurality of object features using a first CAVE model of the sequence of CAVE models;
determining the hand part map for grasping the object based on the contact map and the plurality of object features using a second CAVE model of the sequence of CAVE models; and
determining the direction map for grasping the object based on the hand part map and the plurality of object features using a third CAVE model of the sequence of CAVE models.

14. The system of claim 11, wherein the representation of the hand grasping the object is based on a part-wise Signed Distance Function (SDF) hand model, wherein the representation of the hand grasping the object comprises multiple pose parameters corresponding to multiple hand parts contacting the object and a shape parameter corresponding to the hand.

15. The system of claim 14, wherein generating a representation of a hand grasping the object based on the contact representation using a model-based optimization algorithm comprises determining the multiple pose parameters corresponding to multiple hand parts grasping the object and the shape parameter corresponding to the hand grasping the object by minimizing a total loss function related to the contact representation using an optimization algorithm.

16. A non-transitory computer-readable medium, storing executable instructions, which when executed by a processing device, cause the processing device to perform operations comprising:
receiving a representation of an object from a client device;
a step for generating a contact representation for hand-object interaction based on the representation of the object, wherein the contact representation comprises a contact map indicating contact points on the representation of the object, a hand part map indicating hand parts contacting the object, and a direction map comprising contact directions of the hand parts contacting the object; and
a step for generating a hand grasp representation with respect to the object based on the contact representation using a model-based optimization algorithm; and
providing the hand grasp representation to the client device.

17. The non-transitory computer-readable medium of claim 16, wherein the representation of the object is a point cloud.

18. The non-transitory computer-readable medium of claim 16, wherein the step for generating a contact representation comprises:
extracting a plurality of object features using a PointNet++ algorithm;
determining the contact map for grasping the object based on the plurality of object features using a first CAVE model of a sequence of CAVE models;
determining the hand part map for grasping the object based on the contact map and the plurality of object features using a second CAVE model of the sequence of CAVE models; and
determining the direction map for grasping the object based on the hand part map and the plurality of object features using a third CAVE model of the sequence of CAVE models.

19. The non-transitory computer-readable medium of claim 16, wherein the representation of the hand grasping the object is based on a part-wise Signed Distance Function (SDF) hand model, wherein the representation of the hand grasping the object comprises multiple pose parameters corresponding to multiple hand parts contacting the object and a shape parameter corresponding to the hand.

20. The non-transitory computer-readable medium of claim 19, wherein the step for generating a hand grasp representation with respect to the object comprises:
determining the multiple pose parameters corresponding to multiple hand parts grasping the object and the shape parameter corresponding to the hand grasping the object by minimizing a total loss function related to the contact representation using an optimization algorithm.
